(19) United States
(12) Patent Application Publication
(10) Pub. No.: US 2025/0027196 A1
(43) Pub. Date: Jan. 23, 2025

(54) METHOD OF FORMING ALLOY THIN FILM USING ATOMIC LAYER DEPOSITION PROCESS INCLUDING OPTIMAL UNIT PROCESS, AND ELECTRONIC ELEMENT MANUFACTURED USING THE SAME

(71) Applicant: INDUSTRY-UNIVERSITY COOPERATION FOUNDATION HANYANG UNIVERSITY ERICA CAMPUS, Ansan-si (KR)

(72) Inventors: Taejoo PARK, Ansan-si Gyeonggi-do (KR); Jiwon HAN, Ansan-si (KR)

(73) Assignee: INDUSTRY-UNIVERSITY COOPERATION FOUNDATION HANYANG UNIVERSITY ERICA CAMPUS, Ansan-si (KR)

(21) Appl. No.: 18/908,629

(22) Filed: Oct. 7, 2024

Related U.S. Application Data
(63) Continuation of application No. PCT/KR2023/010338, filed on Jul. 19, 2023.

(30) Foreign Application Priority Data
Jul. 19, 2022 (KR) 10-2022-0089008
Oct. 4, 2022 (KR) 10-2022-0126372

(51) Int. Cl. C23C 16/455; C23C 16/40; C23C 16/44

(52) U.S. Cl. CPC C23C 16/45529; C23C 16/40; C23C 16/4408

(57) ABSTRACT

A method of forming an alloy thin film including a low work function metal through a super-cycle ALD process, the method including performing a first unit process of forming an oxide or nitride of a low-work function metal, and performing a second unit process of forming a film of a different type metal on the oxide or nitride, wherein the second unit process includes (a) injecting a precursor of a source of the different type metal for a first time, (b) injecting a purge gas, (c) injecting a reactant, and (d) injecting a purge gas, and the second unit process further includes, prior to the injecting of the precursor of the source of the different type metal, injecting the precursor of the source of the different type metal for a second time to reduce the low work function metal.

### CROSS-REFERENCE TO RELATED APPLICATION

This application is a continuation of pending PCT International Application No. PCT/KR2023/010338, which was filed on Jul. 19, 2023, and which claims priority to and the benefit of Korean Patent Application No. 10-2022-0089008, which was filed in the Korean Intellectual Property Office on Jul. 19, 2022, and Korean Patent Application No. 10-2022-0126372, which was filed in the Korean Intellectual Property Office on Oct. 4, 2022, the disclosures of which are incorporated herein by reference in their entirety.

### BACKGROUND

### 1. Field of the Invention

The present disclosure relates to a method of forming an alloy thin film using an atomic layer deposition (ALD) process including an optimal unit process, and an electronic element manufactured using the same, and more specifically, to a method of forming an alloy thin film using an ALD process including an optimal unit process in a super-cycle ALD process, and an electronic element manufactured using the same.

### 2. Discussion of Related Art

When an alloy thin film is formed in the related art, an atomic layer deposition (ALD) process should be first performed with a unit material constituting the thin film, it is difficult to deposit a metal thin film including a highly reactive element (such as Ti, Ta, or Al), and it is possible to deposit only materials with high oxidation resistance. Accordingly, there is a limitation in that the scope of technical application is limited to chemically stable materials such as oxides, nitrides, and precious metals.

For example, conventionally, in order to deposit a thin film including two or more types of metal atoms through an ALD process, a super-cycle ALD process in which two or more ALD unit processes are continuously performed in an alternating sequence to form a thin film has been mainly used. However, when a super-cycle ALD is used, two or more ALD unit processes included in the super-cycle ALD process should be first developed, and thus it is impossible to form an alloy thin film including low work function metals such as aluminum (Al), tantalum (Ta), and titanium (Ti), for which it is difficult to develop an ALD-based unit process. Accordingly, an oxide or nitride of low work function metals, which are relatively easy to deposit, are being used as substitutes, but inevitably cause an increase in impurities in a thin film and a degradation in physical and electrical properties.

In addition, when a metal thin film is deposited according to the related art, due to the characteristics of metal materials having high surface energy, an island growth phenomenon in which separate nuclei are generated and grow in the early stage of growth inevitably occurs. Therefore, in order for nuclei to be grown and connected to form a thin film, a thickness of a certain level or more is required, which acts as a critical limiting factor in forming a thin metal film.

### SUMMARY

The present disclosure is directed to providing a method of forming an alloy thin film using an atomic layer deposition (ALD) process including an optimal unit process in which a unit process used in an existing super-cycle ALD process is optimized to design and cause a surface reaction that is advantageous for thin film formation, thereby forming an alloy film with low impurity concentration and excellent physical and electrical properties using the same material and device as before, and an electronic element manufactured using the same.

According to an aspect of the present disclosure, there is provided a method of forming an alloy thin film including a low work function metal through an ALD process, the method including performing a first unit process of forming an oxide or nitride of a low-work function metal, and performing a second unit process of forming a film of a different type metal on the oxide or nitride, wherein the second unit process includes (a) injecting a precursor of a source of the different type metal for a first time, (b) injecting a purge gas, (c) injecting a reactant, and (d) injecting a purge gas, and the second unit process further includes, prior to the injecting of the precursor of the source of the different type metal, injecting the precursor of the source of the different type metal for a second time to reduce the low work function metal.

The second time may be substantially the same as the first time.

The injecting for the second time may include effectively removing oxygen present in a form of an OH functional group on a surface of the low work function metal immediately after the first unit process.

The injecting for the second time may include sufficiently removing oxygen combined with the low work function metal immediately after the first unit process to allow the alloy thin film to have a low resistivity of 3.5 mΩ·cm or less.

The injecting for the second time may include optimizing a surface reaction of the film of the different type metal and an oxide thin film of the low work function metal to convert the oxide thin film of the low work function metal from an insulating chemical state to a conductive metal sub-oxide.

The oxide thin film of the low work function metal may be continuously formed with respect to the film of the different type metal undergoing island growth to electrically connect islands of the film of the different type metal and then induce layer-by-layer growth of the film of the different type metal deposited thereon to improve continuity of the film itself of the different type metal.

The injecting for the second time may include optimizing a surface reaction of the film of the different type metal and an oxide thin film of the low work function metal to reduce an oxidation number of the low work function metal in the oxide thin film of the low work function metal.

The source of the different type metal may be selected from Ru, Pt, Ir, Ag, Au, Mo, and Co. In addition to the materials listed, the source of the different type metal may be selected from any material capable of metal deposition.

The first unit process may include injecting a precursor of the low work function metal source, injecting a purge gas, injecting a reactant, and injecting a purge gas.

The low work function metal source may be selected from Ti, Al, Ta, Hf, Zr, Nb, Sn, Mo, Pt, Ru, and Ir. In addition to the materials listed, the low work function metal source may be selected from any material that can be deposited by ALD.

According to another aspect of the present disclosure, there is provided a method of forming an alloy thin film including a low work function metal through an ALD process, the method including performing a first unit ALD process of forming an oxide of a low-work function metal, and performing a second unit ALD process of forming a film of different type metal on the oxide, wherein the second unit ALD process includes injecting a subsequent precursor to form a sub-oxide of the low work function metal.

According to still another aspect of the present disclosure, there is provided an electronic element including an alloy thin film manufactured through the method of forming an alloy thin film including a low work function metal through a super-cycle ALD process.

### BRIEF DESCRIPTION OF THE DRAWINGS

The above and other objects, features and advantages of the present disclosure will become more apparent to those of ordinary skill in the art by describing exemplary embodiments thereof in detail with reference to the accompanying drawings, in which:

FIG. 1 is a sequence diagram of a conventional super-cycle atomic layer deposition (ALD) process;

FIG. 2 is a sequence diagram of a super-cycle ALD process according to an embodiment of the present disclosure;

FIG. 3 is a schematic diagram illustrating a difference in surface reaction during super-cycle ALD processes according to an embodiment of the present disclosure and the related art;

FIGS. 4A and 4B show results of optimizing precursor and reactant injection times in a subsequent Ru unit process according to an embodiment of the present disclosure;

FIG. 5 is a graph showing a comparison between the resistivity of a Ru—Ta thin film deposited through a super-cycle ALD process according to an embodiment of the present disclosure and the resistivity of a Ru—Ta thin film according to the related art;

FIG. 6 is a sequence diagram illustrating a process of controlling a composition of a Ru—Ta thin film by controlling a ratio of unit processes constituting a super-cycle ALD process of forming a Ru—Ta thin film according to an embodiment of the present disclosure;

FIG. 7 is a graph showing a composition ratio of Ru and Ta in a thin film according to a cycle ratio of a Ru unit process and a Ta₂O₅ unit process in a super-cycle ALD process of a Ru—Ta thin film according to an embodiment of the present disclosure;

FIG. 8 shows results of analyzing a change in resistivity of a Ru—Ta thin film according to a thickness for each cycle ratio according to an embodiment of the present disclosure;

FIG. 9 is a graph showing an electrically critical thickness (ECT) of a Ru—Ta thin film, at which conductivity is exhibited, and resistivity at the ECT according to an embodiment of the present disclosure;

FIGS. 10A and 10B are a graph showing results of analyzing a chemical binding state of a thin film using X-ray photoelectron spectroscopy according to an embodiment of the present disclosure;

FIG. 11 shows schematic diagrams illustrating the growth behavior of a Ru—Ta thin film deposited according to the related art;

FIG. 12 shows schematic diagrams illustrating the growth behavior of a Ru—Ta thin film to which a super-cycle ALD process is applied according to an embodiment of the present disclosure; and

FIG. 13 shows schematic diagrams showing a comparison between growth behaviors of an existing ALD Ru thin film and a Ru—Ta thin film deposited through a super-cycle ALD process according to an embodiment of the present disclosure.

### DETAILED DESCRIPTION

The advantages and features of the present disclosure and methods of accomplishing the same will become apparent from the following description of embodiments in detail, taken in conjunction with the accompanying drawings. However, the present disclosure is not limited to the embodiments disclosed herein but will be implemented in various forms. The embodiments are provided so that the present disclosure is completely disclosed, and a person of ordinary skilled in the art can fully understand the scope of the present disclosure. Therefore, the present disclosure will be defined only by the scope of the appended claims. Like reference numerals refer to like elements throughout the specification.

Terms used herein are for the purpose of describing embodiments only and are not intended to limit the present disclosure. As used herein, the singular forms are intended to include the plural forms as well, unless the context clearly indicates otherwise. It will be further understood that the terms “comprise” and/or “comprising” used in this specification specify the presence of stated components, steps, operations, and/or elements, but do not preclude the presence or addition of one or more other components, steps, operations, and/or elements thereof.

In addition, embodiments described herein will be described with reference to cross-sectional views and/or plan views which are ideal exemplary views of the present disclosure. In drawings, thicknesses of films and regions are exaggerated for effective description of technical contents. Therefore, the form of the exemplary views may be modified by manufacturing techniques and/or tolerances, an allowable error, or the like. Therefore, the embodiments of the present disclosure are not limited to a specific form which is shown but include variations according to the manufacturing process. For example, an etching region shown at a right angle may be rounded or have a shape with a certain curvature. Accordingly, the regions illustrated in the drawings are schematic in nature, and the shapes of the regions illustrated in the drawings are intended to illustrate the specified shape of a region of a device and are not intended to limit the scope of the present disclosure.

In a method of forming an alloy thin film according to an embodiment of the present disclosure, in a super-cycle atomic layer deposition (ALD) process, a unit process is performed for forming a thin film of compounds such as an oxide and a nitride that are easy to deposit to form a thin film, and impurities such as oxygen and nitrogen are removed by optimizing a subsequent unit process in consideration of a surface reaction. Thus, without a deposition process of a single metal that is difficult to deposit, an alloy thin film including the single metal can be deposited. According to the present disclosure, while the same material and device used in the conventional ALD process are used, material limitations are overcome through surface reaction control, and an alloy thin film, which is difficult to form with existing technologies, can be deposited.

As described above, conventionally, in order to deposit a thin film including two or more types of metal atoms through an ALD process, a super-cycle ALD process in which two or more ALD unit processes are continuously performed in an alternating sequence to form a thin film has been mainly used. However, when a super-cycle ALD process is used, two or more ALD unit processes included in the super-cycle ALD process should be first developed, and thus it is impossible to form an alloy thin film including low work function metals such as aluminum (Al), tantalum (Ta), and titanium (Ti), for which it is difficult to develop an ALD-based unit process. Accordingly, an oxide or nitride of low work function metals, which are relatively easy to deposit, are being used as substitutes, but inevitably cause an increase in impurities in a thin film and a degradation in physical and electrical properties.

According to the present disclosure, a precursor injection time of unit processes that constitute a super-cycle ALD process is optimized to maximize a surface reaction between unit processes, thereby removing oxygen and nitrogen from a thin film of a low work function metal oxide and nitride. In this case, a precursor injection operation in the unit process includes a precursor injection operation of reducing a lower film in addition to existing precursor injection. As a result, an alloy thin film in which oxygen or nitrogen impurities are minimized in the thin film may be formed through a super-cycle ALD process using an ALD process for a low work function metal compound. In addition, when a metal thin film is deposited according to the related art, due to the characteristics of metal materials having high surface energy, an island growth phenomenon in which separate nuclei are generated and grow in the early stage of growth inevitably occurs. Therefore, in order for nuclei to be grown and connected to form a thin film, a thickness of a certain level or more is required, which acts as a critical limiting factor in forming a thin metal film. According to the present disclosure, a thin film in the form of oxide and nitride, which are very easy to deposit as compared to pure metals, may be used in a process to improve the continuity of the thin film, thereby forming a thin film having high conductivity even at a very thin thickness. In addition, the electrical properties of the thin film can be freely controlled according to the properties and composition of each metal that constitutes the thin film.

According to the present disclosure, by optimizing an ALD precursor injection time in consideration of an interaction between unit processes constituting a super-cycle ALD process, even while an ALD-based alloy thin film, which has been impossible to form with the related art, is formed, and since the same process sequence and material as the related art are used, there has a special advantage in that additional devices or materials are not required for application of the present disclosure. These features may be suitable for next-generation products, which are currently undergoing extreme miniaturization, in the semiconductor industry and may contribute to securing future market competitiveness.

Since a super-cycle ALD process according to an embodiment of the present disclosure relates to a method of forming an alloy thin film including a low work function metal, and in the present disclosure, may be referred to as a method of forming an alloy thin film including a low work function metal through a super-cycle ALD process. In addition, the super-cycle ALD process may include an optimal unit process and thus may be referred to as a method of forming an alloy thin film using ALD including an optimal unit process. However, hereinafter, for convenience of description, a super-cycle ALD process will be referred to.

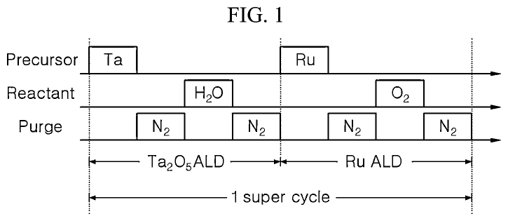

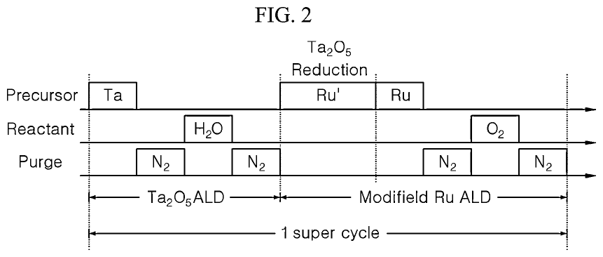

FIGS. 1 and 2 are a sequence diagram of a conventional super-cycle ALD process and a sequence diagram of a super-cycle ALD process according to an embodiment of the present disclosure, respectively. As an example, FIGS. 1 and 2 are sequence diagrams of a process of depositing a ruthenium (Ru)-tantalum (Ta) alloy thin film. As shown in the drawings, one super-cycle may include one cycle of a Ta₂O₅ ALD process and one cycle of a Ru ALD process as unit processes, and the super-cycle may be repeatedly performed to form a Ru—Ta alloy thin film.

Referring to FIG. 2, the super-cycle ALD process according to the embodiment of the present disclosure is an ALD process (see Modified Ru ALD in the drawing) including an additional Ru precursor injection operation (see Ru′ in the drawing) of reducing lower Ta₂O₅ (see Ta₂O₅ Reduction in the drawing) as compared to FIG. 1, and an optimal process time for the super-cycle ALD is secured to optimize a Ru unit process.

More specifically, as shown in FIG. 2, the Ta₂O₅ ALD process (hereinafter referred to as a “first unit process” or a “first unit ALD process”) includes an operation (see Ta in the drawing) of injecting a Ta precursor, an operation (see N₂ in the drawing) of injecting N₂ gas as a purge gas, an operation (see H₂O in the drawing) of injecting H₂O as a reactant, and an operation (see N₂ in the drawing) of injecting N₂ gas as a purge gas. The modified Ru ALD process (hereinafter referred to as a “second unit process” or a “second unit ALD process”) includes an operation (see Ru in the drawing) of injecting a Ru precursor, an operation (N₂ in the drawing) of injecting N₂ gas as a purge gas, an operation (see O₂ in the drawing) of injecting O₂ as a reactant, and an operation (see N₂ in the drawing) of injecting N₂ gas as a purge gas, wherein the modified Ru ALD process further includes an operation (see Ru′ in the drawing) of injecting an additional Ru precursor prior to the operation of injecting the Ru precursor.

According to an embodiment of the present disclosure, the operation Ru′ of injecting the additional Ru precursor and the operation Ru of injecting the Ru precursor may use the same precursor, and thus the same process may be performed for a longer time. Although both the operation Ru′ and the operation Ru may be separate processes, since the operation Ru′ and the operation Ru use the same precursor, it is more advantageous to perform one process for a long time. Each operation may have a certain duration time, and when a duration time of the operation Ru of injecting the Ru precursor is assumed to be a first time, a duration time of the operation Ru′ of injecting the additional Ru precursor may be a second time. Considering the temporal order, the second time is a time that is earlier than the first time, but for the sake of comparison with FIG. 1, reference will be made as described above. The first and second times may each be as short as a few seconds (for example, in a range of 1 second to 10 seconds). This will be described below.

In the first unit process, TaCl₄, TaBr₄, TaF₄, t-butylimino-tris(diethylamino)tantalum (TBTDET), pentakis(ethylmethylamino)tantalum (PEMAT), pentakis(dimethylamino)tantalum (PDMAT), pentakis(diethylamino)tantalum (PDEAT), tertiary amyl imido-tris-dimethylamido tantalum (TAIMATA), or the like may be used as the Ta precursor, in addition to N₂, an inert gas such as Ar, Ne, He, or H₂ may be used as the purge gas, and H₂O, H₂O₂, O₂, O₃, NH₃, H₂, N₂, tBuNH₂, AyNH₂, Me₂NNH₂, or a mixed gas thereof may be used as the reactant.

In the second unit process, Ru(EtCp)₂, Ru(i-PrCp)₂, RuCp₂, Ru(OD)₃, Ru(THD)₃, Ru(THD)₂COD, Ru(MeCp)₂, RuCl₃, CpRu(CO)₃, Ru₃(CO)₁₂, Ru(acac)₃, dicarbonyl-bis(5-methyl-2,4-hexane-diketonato)Ru(II) (Carish), Ru₂{μ₂-η³—N(tBu)—C(H)—C(iPr)}(CO)₆ (T-Rudic), or the like may be used as the Ru precursor, in addition to N₂, an inert gas such as Ar, Ne, or He, or H₂ may also be used as the purge gas, and O₂, O₃, H₂O, H₂O₂, NH₃, H₂, N₂, tBuNH₂, AyNH₂, Me₂NNH₂, or a mixed gas thereof may be used as the reactant.

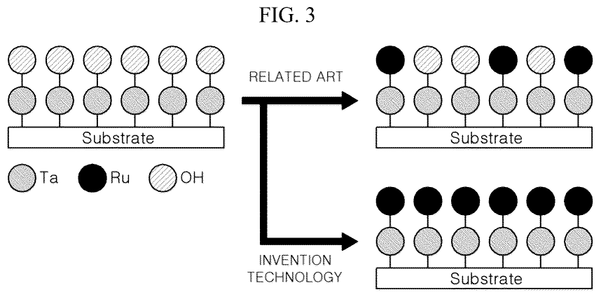

FIG. 3 is a schematic diagram illustrating a difference in surface reaction during super-cycle ALD processes according to an embodiment of the present disclosure and the related art. As shown in FIG. 3, in the case of the related art, since surface functional groups and surface reactions of each unit process are not considered, only a small amount of OH functional groups present on a surface may be removed when a Ru precursor is injected after a Ta₂O₅ unit process. Meanwhile, in the case of the embodiment of the present disclosure, by optimizing a Ru process after a Ta₂O₅ unit process, oxygen present in the form of an OH functional group on a surface immediately after a Ta₂O₅ process may be effectively removed.

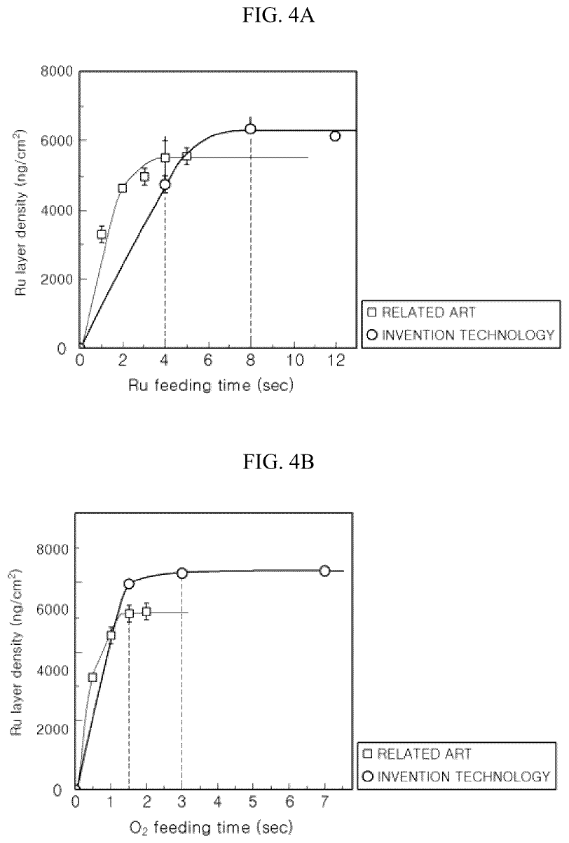

FIGS. 4A and 4B show results of optimizing precursor and reactant injection times in a subsequent Ru unit process according to an embodiment of the present disclosure. Referring to FIG. 4A, when a Ru precursor injection time of an existing operation Ru (see FIG. 1) of injecting a Ru precursor is 4 seconds, Ru precursor injection times (that is, the first time and the second time) of operations Ru′ and Ru (see FIG. 2) of injecting a Ru precursor according to the embodiment of the present disclosure may be 8 seconds. That is, the operations Ru′ and Ru of injecting the Ru precursor last 4 seconds longer than before.

Meanwhile, in the embodiments of FIGS. 4A and 4B, a time (that is, the second time) taken to inject a precursor for lower film reduction may be changed by various variables such as a lower film material, a precursor, and a process temperature.

Referring to FIG. 4B, when an existing reactant (O₂) injection time is 1.5 seconds, a reactant (O₂) injection time according to the embodiment of the present disclosure may be 3 seconds. Even in this case, a reactant injection time may be changed according to various variables such as a lower film material, a precursor, and a process temperature.

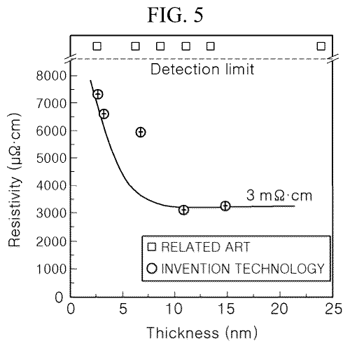

FIG. 5 is a graph showing a comparison between the resistivity of a Ru—Ta thin film deposited through a super-cycle ALD process according to an embodiment of the present disclosure and the resistivity of a thin film according to the related art. In the case of a thin film deposited according to the related art, a surface reaction does not completely occur, and thus a mixed thin film of Ta₂O₅ and Ru is formed to form a thin film having a very high resistivity. On the other hand, according to the embodiment of the present disclosure, oxygen combined with Ta is sufficiently removed in an operation of injecting a Ru precursor, thereby forming a metallic thin film having a low resistivity of 3.5 mΩ·cm or less. Preferably, the metallic thin film having a resistivity of 3 mΩ·cm may be formed.

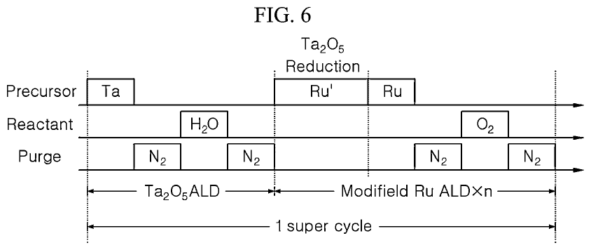

FIG. 6 is a sequence diagram illustrating a process of controlling a composition of a Ru—Ta thin film by controlling a ratio of unit processes constituting a super-cycle ALD process of forming a Ru—Ta thin film according to an embodiment of the present disclosure. A composition of a thin film is controlled by adjusting the number of cycles of each unit process. That is, a process may be performed by repeating the Ru unit process n times as one super-cycle, and as n increases, a percentage of Ru in the thin film may increase. In the following embodiments, a process including n Ru unit processes is expressed as 1:n.

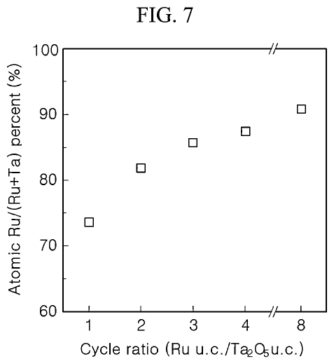

FIG. 7 is a graph showing a composition ratio of Ru and Ta in a thin film according to a cycle ratio of a Ru unit process and a Ta₂O₅ unit process in a super-cycle ALD process of a Ru—Ta thin film according to an embodiment of the present disclosure and showing results of analyzing the composition ratio of the Ru—Ta thin film using X-ray fluorescence (XRF). As shown in FIG. 7, it can be seen that a percentage Ru/(Ru+Ta) of Ru increases as the cycle ratio increases.

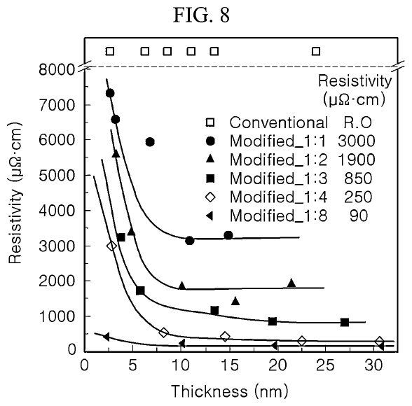

FIG. 8 shows results of analyzing a change in resistivity of a Ru—Ta thin film according to a thickness for each cycle ratio according to an embodiment of the present disclosure. As shown in FIG. 8, as the cycle ratio (or n) increases, the resistivity of the thin film decreases, which is a result of the increase in the percentage of Ru confirmed in FIG. 7.

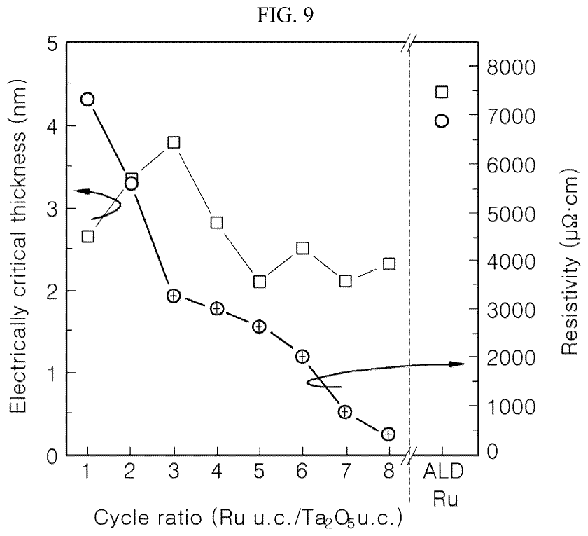

FIG. 9 is a graph showing an electrically critical thickness (ECT) of a Ru—Ta thin film, at which conductivity is exhibited, and resistivity at the ECT according to an embodiment of the present disclosure. As shown in FIG. 9, as a cycle ratio increased, the ECT, at which conductivity was exhibited, and the resistivity at the ECT decreased. In addition, both the ECT and the resistivity of the Ru—Ta thin film deposited through the present disclosure had better values as compared to a Ru thin film (ALD Ru) deposited according to the related art.

In an embodiment of the present disclosure, considering the ECT and the resistivity at the ECT, a Ru—Ta thin film having a cycle ratio of about 1:8 to 1:9 may have the lowest resistivity at a thickness of about 2.2 nm, which corresponds to an optimal process for use in the application field according to the embodiment of the present disclosure presented above. Meanwhile, since physical properties change according to a composition of a deposited thin film, when applied to other fields, a process with a different cycle ratio may be used as an optimal process according to the purpose of a thin film.

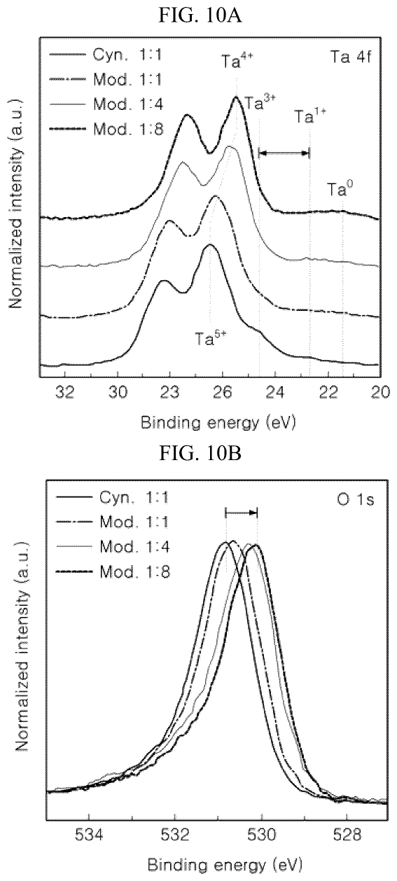

FIGS. 10A and 10B are a graph showing results of analyzing a chemical binding state of a thin film using X-ray photoelectron spectroscopy (XPS) according to an embodiment of the present disclosure. That is, FIGS. 10A and 10B show results of analyzing a chemical binding state of Ta and O in the thin film. As shown in FIGS. 10A and 10B, in the case of the related art, it can be seen that Ta in the thin film is present in the form of Ta₂O₅ with an oxidation number of +5. In the case of a modified 1:n sample to which a super-cycle ALD process according to an embodiment of the present disclosure was applied, it was confirmed that Ta and O had lower binding energy as compared to the related art indicated as conventional, and the difference became larger as n increased. This showed that, as described above, the optimal Ru process to which the super-cycle ALD process according to the embodiment of the present disclosure was applied had an effect of effectively removing oxygen combined with Ta and reducing Ta.

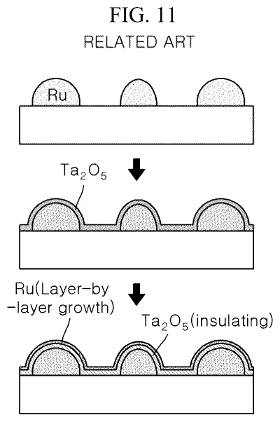

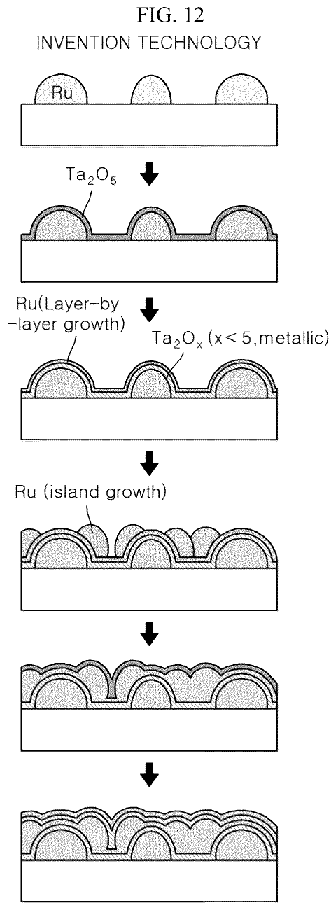

FIGS. 11 and 12 show schematic diagrams illustrating a growth behavior of a Ru—Ta thin film deposited according to the related art and a growth behavior of a Ru—Ta thin film deposited through a super-cycle ALD process according to an embodiment of the present disclosure, respectively. Referring to FIGS. 11 and 12, in the case of the related art, since a chemical state of a Ta₂O₅ thin film is maintained in an insulating state, a thin film having conductivity cannot be deposited. When the super-cycle ALD process according to the embodiment of the present disclosure is applied, a Ta₂O₅ thin film is reduced and changed into a (metallic) Ta sub-oxide with conductivity by optimizing a Ru unit process and a surface reaction of a lower Ta₂O₅ thin film. Unlike Ru which exhibits island growth, such a Ta oxide film is continuously formed even at a thin thickness, thereby exhibiting an effect of electrically connecting Ru islands. In addition, the continuity of a Ru thin film itself can be improved by inducing layer-by-layer growth of Ru deposited at an upper side. As a result, a Ru—Ta thin film having a low resistivity even at a thin thickness may be formed.

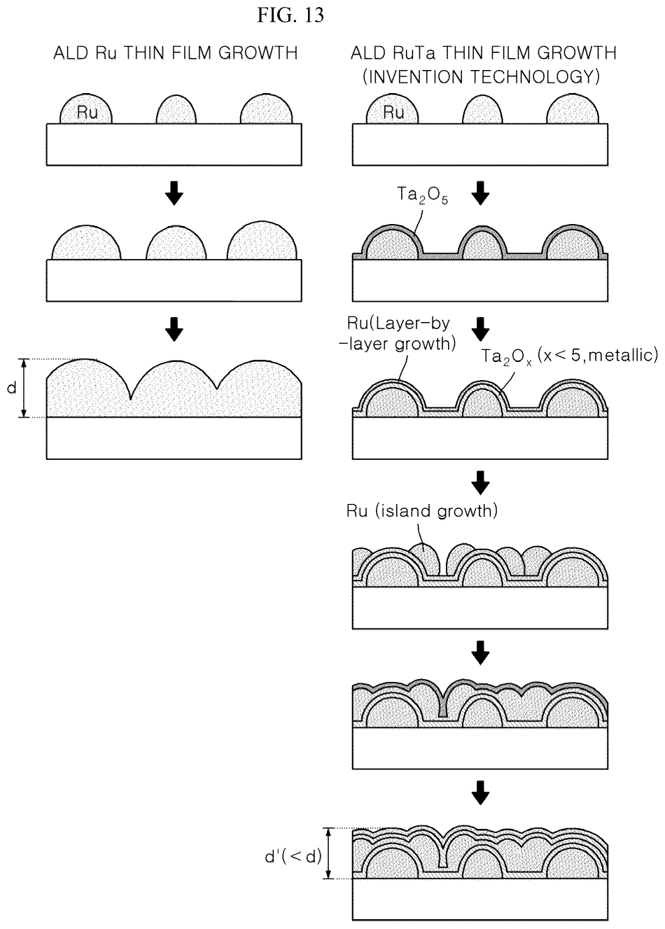

FIG. 13 shows schematic diagrams showing a comparison between growth behaviors of an existing ALD Ru thin film and a Ru—Ta thin film deposited through a super-cycle ALD process according to an embodiment of the present disclosure. As shown in FIG. 13, in the case of Ru, due to island growth, in order to form a continuous thin film, a thickness d of a thin film should be at least a certain level or more. However, in the case of the Ru—Ta thin film to which the super-cycle ALD process according to the embodiment of the present disclosure is applied, a Ta oxide thin film with high continuity and conductivity compensates for insufficient continuity of Ru, thereby securing a continuous metal film even at a thin thickness d′ (d′<d).

Meanwhile, in the embodiment of the present disclosure, description has been provided using Ru, but since island growth is a phenomenon that commonly occurs when most metal films are formed, the embodiment of the present disclosure may be applied when all metal films of Pt, Ir, Ag, Au, Mo, and Co as well as Ru are formed.

In addition, the above-described embodiment is an example of a Ru—Ta thin film using Ru and Ta₂O₅, but since the present disclosure relates to a method of controlling a surface reaction between unit processes, the scope of application is not limited to the above-described materials, and any material such as Ti, Al, Ta, Hf, Zr, Nb, Sn, Mo, Pt, Ru, or Ir, and an oxide and nitride thereof may be used. Additionally, the order in which the unit processes are performed may be changed in various ways in consideration of surface reactions.

The method of forming an alloy thin film according to the embodiment of the present disclosure described above can be applied to all electronic devices such as logic circuits, display devices, memory devices, and sensors, and all devices to which an ALD process is used. The method can be applied to transistors, dynamic random access memories (DRAMs), NAND flash memories, and various sensors. In addition, a method of forming an alloy thin film using an ALD process including an optimal unit process according to an embodiment of the present disclosure can be applied to all ALD processes of a super-cycle ALD type including two or more unit processes. In addition, the method of forming an alloy thin film using an ALD process including an optimal unit process according to the embodiment of the present disclosure may be an ALD process including a process optimization operation in which a surface reaction between unit processes is considered when a super-cycle ALD process is performed. In addition, the method of forming an alloy thin film using an ALD process including an optimal unit process according to the embodiment of the present disclosure may be an ALD process including a subsequent precursor injection operation of forming a metal sub-oxide when a super-cycle ALD process is performed. In addition, the method of forming an alloy thin film using an ALD process including an optimal unit process according to the embodiment of the present disclosure may be a thin film manufacturing process in which materials having both high surface energy and conductivity which are advantageous in forming a metal thin film, are mixed and used when thin film is formed.

According to the present technology, a unit process used in an existing super-cycle ALD process is optimized to design and cause a surface reaction that is advantageous for thin film formation, thereby forming an alloy film with low impurity concentration and excellent physical and electrical properties using the same material and device as before.

In addition, since the present technology uses the same material and device as existing technologies, the present technology has broad potential for immediate application without separate device investment.

Although the technical idea of the present disclosure has been described in detail according to the above-described exemplary embodiments, it should be noted that the above embodiments are intended to illustrate the present disclosure, not to limit the scope of the present disclosure. Additionally, a person skilled in the art will appreciate that various embodiments are possible within the scope of the technical idea of the present disclosure.

What is claimed is:

1. A method of forming an alloy thin film including a low work function metal through a super-cycle atomic laser deposition (ALD) process, the method comprising:
performing a first unit process of forming an oxide or a nitride of the low work function metal; and
performing a second unit process of forming a film of a different type metal on the oxide or the nitride,
wherein the second unit process includes (a) injecting a precursor of a source of the different type metal for a first time, (b) injecting a purge gas, (c) injecting a reactant, and (d) injecting a purge gas, and
the second unit process further includes, prior to the injecting of the precursor of the source of the different type metal, injecting the precursor of the source of the different type metal for a second time to reduce the low work function metal.

2. The method of claim 1, wherein the second time is substantially the same as the first time.

3. The method of claim 1, wherein the injecting for the second time includes effectively removing oxygen present in a form of an OH functional group on a surface of the low work function metal immediately after the first unit process.

4. The method of claim 1, wherein the injecting for the second time includes sufficiently removing oxygen combined with the low work function metal immediately after the first unit process to allow the alloy thin film to have a low resistivity of 3.5 mΩ·cm or less.

5. The method of claim 1, wherein the injecting for the second time includes optimizing a surface reaction of the film of the different type metal and an oxide thin film of the low work function metal to convert the oxide thin film of the low work function metal from an insulating chemical state to a conductive metal sub-oxide.

6. The method of claim 5, wherein the oxide thin film of the low work function metal is continuously formed with respect to the film of the different type metal undergoing island growth to electrically connect islands of the film of the different type metal and then induce layer-by-layer growth of the film of the different type metal deposited thereon to improve continuity of the film itself of the different type metal.

7. The method of claim 1, wherein the injecting for the second time includes optimizing a surface reaction of the film of the different type metal and an oxide thin film of the low work function metal to reduce an oxidation number of the low work function metal in the oxide thin film of the low work function metal.

8. The method of claim 1, wherein the source of the different type metal is selected from Ru, Pt, Ir, Ag, Au, Mo, and Co.

9. The method of claim 1, wherein the first unit process includes (1) injecting a precursor of a source of the low work function metal, (2) injecting a purge gas, (3) injecting a reactant, and (4) injecting a purge gas.

10. The method of claim 9, wherein the source of the low work function metal is selected from Ti, Al, Ta, Hf, Zr, Nb, Sn, Mo, Pt, Ru, and Ir.

11. A method of forming an alloy thin film including a low work function metal through a super-cycle atomic laser deposition (ALD) process, the method comprising:
performing a first unit ALD process of forming an oxide of the low work function metal; and
performing a second unit ALD process of forming a film of different type metal on the oxide,
wherein the second unit ALD process includes a subsequent precursor injection operation of forming a sub-oxide of the low work function metal.

12. An electronic element comprising an alloy thin film manufactured through the method of forming an alloy thin film including a low work function metal through a super-cycle ALD process of claim 1.
